(19) United States
(12) Patent Application Publication
(10) Pub. No.: US 2024/0062986 A1
(43) Pub. Date: Feb. 22, 2024

(54) Charged Particle Beam Device

(71) Applicant: Hitachi High-Tech Corporation, Minato-ku, Tokyo (JP)

(72) Inventors: Naho TERAO, Tokyo (JP); Toshiyuki YOKOSUKA, Tokyo (JP); Hideyuki KOTSUJI, Tokyo (JP); Tomohito NAKANO, Tokyo (JP); Hajime KAWANO, Tokyo (JP)

(21) Appl. No.: 18/270,937

(22) PCT Filed: Mar. 1, 2021
(86) PCT No.: PCT/JP2021/007766

§ 371 Date: Jul. 5, 2023

(51) Int. Cl. H01J 37/02; H01J 37/28; H01J 37/244; H01J 37/22

(52) U.S. Cl. CPC H01J 37/026; H01J 37/28; H01J 37/244; H01J 37/222; H01J 2237/2817; H01J 2237/0656; H01J 2237/30483

(57) ABSTRACT

The purpose of the present invention is to provide a charged particle beam device that can specify irradiation conditions for primary charged particles that can obtain a desired charged state without adjusting the acceleration voltage. The charged particle beam device according to the present invention specifies the irradiation conditions for a charged particle beam in which the charged state of a sample is switched between a positive charge and a negative charge, and adjusts the irradiation conditions according to the relationship between the specified irradiation conditions and the irradiation conditions when an observation image of the sample has been acquired (see FIG. 8).

### TECHNICAL FIELD

The present invention relates to a charged particle beam device.

### BACKGROUND ART

Along with miniaturization and high integration of a semiconductor pattern, a slight shape difference affects operating properties of a device, and needs for shape management have increased. Therefore, for a scanning electron microscope (SEM) used for inspecting and measuring a semiconductor, high sensitivity and high accuracy are further required than in the related art. The scanning electron microscope is a device that detects electrons emitted from a sample, generates a signal waveform by detecting the electrons, and measures, for example, a dimension between peaks (pattern edges).

Recently, as a technique of forming a fine pattern having a size of 10 nm or less on a wafer, introduction of extreme ultraviolet (EUV) lithography has progressed. In the EUV lithography, it is known that randomly occurring defects called stochastic defects cause a problem. As a result, needs for inspecting the entire wafer surface have increased, and a higher throughput is required for an inspection device.

To increase the inspection efficiency (throughput), it is considered to inspect a wide range of area at once using low magnification imaging by a high current. On the other hand, when a sample is a material to be charged, the influence of charge appears more significantly in the low magnification observation, and various phenomena that decrease the inspection accuracy, for example, image distortion, shading (brightness unevenness), or abnormal contrast occur. Accordingly, to apply low observation imaging to a pattern formed of a material to be charged, such as a resist, it is necessary to control the charging phenomenon.

The charge of the sample is determined by a balance between incident charged particles (for example, primary electrons) and charged particles emitted from the sample (for example, secondary electrons or backscattered electrons). When the charged particles are electrons, the emission rate (secondary electron yield) of the secondary electrons depends on the energy of the incident electrons. Accordingly, by adjusting the energy of the primary electrons with which the sample is irradiated, charge formed on the sample can be prevented.

PTL 1 describes a control of the energy of incident electrons as a method of controlling charge of a sample. PTL 2 discloses a method of calculating distortion of a SEM image as a feature amount of the SEM image and, when the distortion amount exceeds an allowable value, estimating a cause for a phenomenon from a library and displaying the estimation result. PTL 3 discloses a method of comparing a signal waveform obtained by one-dimensional scanning before charging and a signal waveform obtained by two-dimensional scanning for visualizing charge to each other to correct an image where distortion occurs.

### CITATION LIST

### Patent Literature

PTL 1: JP2002-310963A
PTL 2: JP2012-053989A
PTL 3: JP2019-067545A

### SUMMARY OF INVENTION

### Technical Problem

By changing the energy of the primary electrons with which the sample is irradiated as disclosed in PTL 1, the emission rate of the secondary electrons can be controlled, and the charge of the sample can be controlled. On the other hand, to switch acceleration conditions depending on patterns (materials or shapes), setting, adjustment, or the like of optical conditions corresponding to the acceleration is necessary. Accordingly, when the technique described in PTL 1 is applied to a wafer where a plurality of patterns are present, an effect of implementing high throughput is limited.

PTLs 2 and 3 disclose a method of evaluating image distortion that appears as a result of charging and utilizing the image distortion in a post-process such as image correction. However, such documents do not describe irradiation conditions of the primary electrons necessary for controlling the charged state of the sample to a desired state.

In the charged particle beam device of the related art, a configuration of specifying irradiation conditions of the primary electrons where the sample is controlled to a desired charged state (or a feature amount of an observation image can be suitably acquired) without adjusting an acceleration voltage is not sufficiently considered.

The present invention has been made in consideration of the above-described problems, and an object thereof is to provide a charged particle beam device that can specify irradiation conditions of primary charged particles where a desired charged state can be obtained with changing optical conditions other than acceleration or adjusting optical conditions.

### Solution to Problem

A charged particle beam device according to the present invention specifies irradiation conditions of a charged particle beam where a charged state of a sample switches between positive charge and negative charge, and adjusts the irradiation conditions according to a relationship between the specified irradiation conditions and the irradiation conditions where an observation image of the sample is acquired.

### Advantageous Effects of Invention

The charged particle beam device according to the present invention can specify irradiation conditions of primary charged particles where a desired charged state can be obtained without adjusting an acceleration voltage.

### BRIEF DESCRIPTION OF DRAWINGS

FIG. 1 is a schematic view illustrating a scanning electron microscope 100 according to a first embodiment.

FIG. 2 illustrates a charge distribution (analysis result) on a sample that is formed when a sample surface (no pattern) is scanned while changing an irradiation current amount of a primary electron beam.

FIG. 3 illustrates a relationship between an irradiation current amount and an average potential in a field of view.

FIG. 4 illustrates a relationship between a current density and an average potential in a field of view.

FIG. 5 illustrates a relationship between a current density and an average potential in a field of view depending on each of material properties of a sample.

FIG. 6 illustrates a relationship between a current density and an average potential depending on each of conditions of an electric field (electric field for pulling up secondary electrons emitted from a sample) set on the sample.

FIG. 7 is a diagram illustrating a charged state of a sample and a deflection action.

FIG. 8 illustrates an example of results of evaluating a pattern dimensional ratio depending on positions of a sample in each of charged states.

FIG. 9 illustrates one example of a magnification change when a hole pattern is observed.

FIG. 10 is a flowchart illustrating a procedure of determining irradiation conditions (observation conditions) of a primary electron beam using an arithmetic unit 110.

FIG. 11 is a flowchart illustrating a procedure of determining irradiation conditions (observation conditions) of a primary electron beam using AI.

FIG. 12 is a diagram illustrating a configuration of a learner.

FIG. 13 is a diagram illustrating operating conditions of the present invention.

FIG. 14 illustrates one example of a user interface screen for setting operation conditions of the scanning electron microscope 100 by a user.

FIG. 15 is a flowchart illustrating a procedure of estimating a material property using the arithmetic unit 110.

FIG. 16 illustrates an example of a user interface screen according to a second embodiment.

FIG. 17 illustrates an example of reference data of each of three materials A to C having different film thicknesses.

FIG. 18 is a flowchart illustrating a procedure of estimating a film thickness using the arithmetic unit 110.

FIG. 19 illustrates an example of a user interface screen according to a third embodiment.

### DESCRIPTION OF EMBODIMENTS

### First Embodiment

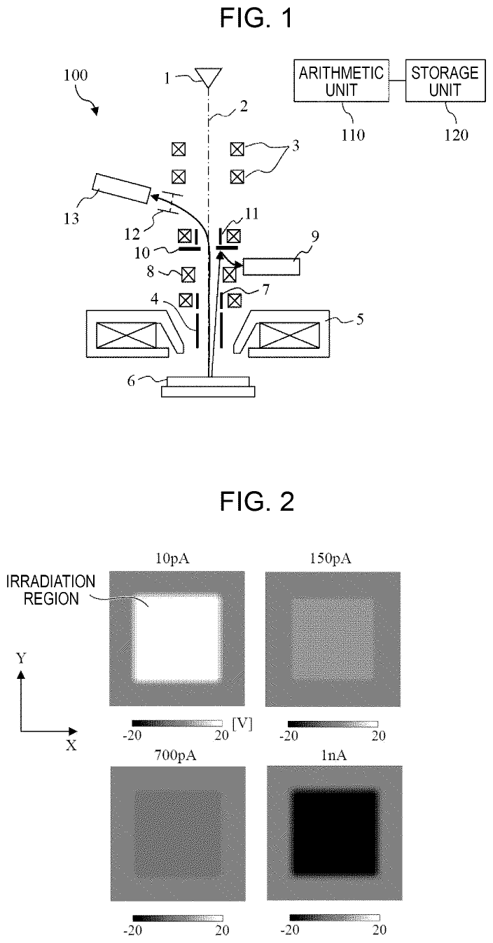

FIG. 1 is a schematic view illustrating a scanning electron microscope 100 (SEM 100, charged particle beam device) according to a first embodiment of the present invention. An electron beam 2 (primary electron beam) generated by an electron gun 1 is focused by a condenser lens 3 and is focused on a sample 6 by an objective lens 5. Here, an aperture angle of the primary electrons can be adjusted by a condenser lens (aperture angle adjusting lens) 8. A deflector 4 (scanning deflector) deflects the electron beam 2 to scan an electron beam scanning region of the sample. The primary electrons are excited in the sample by irradiation during two-dimensional scanning, signal electrons emitted from the sample are detected by a detector 9 and a detector 13, and an arithmetic unit 110 converts the detection signal into an image to acquire the observation image of the sample. The signal electrons emitted from the sample pass through a signal electron deflector 7 to be divided into electrons that pass through a signal electron diaphragm 10 and electrons that collide with the signal electron diaphragm 10. The electrons that collide with the signal electron diaphragm 10 generate tertiary electrons, and the tertiary electrons are detected by the detector 9. The electrons that pass through the signal electron diaphragm 10 are deflected toward the detector 13 through a signal electron deflector 11. In a front stage of the detector 13, an energy filter 12 capable of discriminating signal electrons by energy is provided, and electrons that pass through the filter are detected by the detector 13. The charged state of the sample can be estimated based on a change in signal intensity when a voltage to be applied to the energy filter 12 is changed.

The SEM 100 includes the arithmetic unit 110 and a storage unit 120. The arithmetic unit 110 executes a control of each of optical elements in the scanning electron microscope 100, a control of the voltage to be applied to the energy filter 12, and the like. A negative voltage application power supply (not illustrated) is connected to a sample stage for mounting the sample 6, and by controlling the negative voltage application power supply, the arithmetic unit 110 controls the energy when the primary electron beam arrives at the sample 6. The present invention is not limited thereto, and by controlling an acceleration power supply connected between an acceleration electrode for accelerating the primary electron beam and the electron gun 1, the arithmetic unit 110 may control the energy when the primary electron beam arrives at the sample.

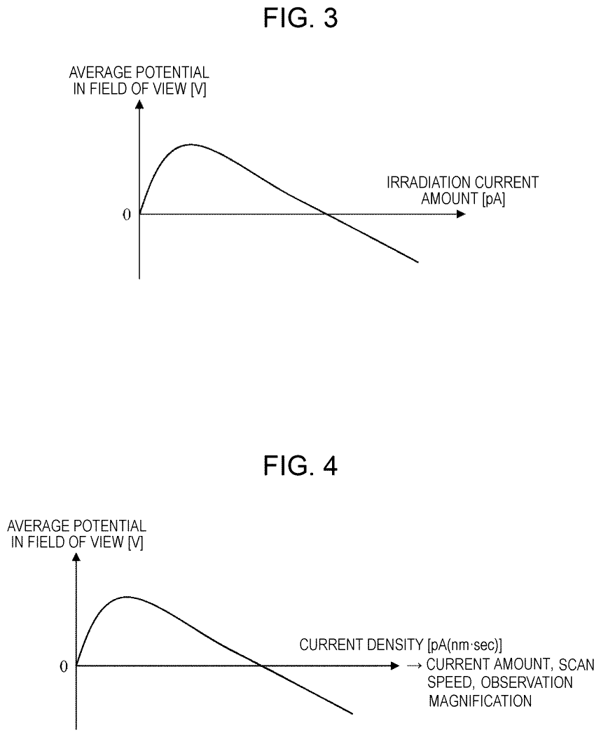

The arithmetic unit 110 also uses a detection signal of the secondary charged particles detected by each of the detectors to generate an observation image of the sample. The storage unit 120 is a storage device that stores data using the arithmetic unit 110. For example, the storage unit 120 can store a data table that describes a relationship described below with reference to FIGS. 3 to 6, an inference model 112 generated by a learner, reference data described in a second embodiment, and the like.

The SEM 100 includes an image memory that stores the detection signal in each of pixels, and the detection signal is stored in the image memory. The arithmetic unit 110 calculates a signal waveform of a region designated in an image based on image data stored in the image memory. A charged state in a field of view is estimated based on a distortion amount (charge estimation parameter) of the image, and an irradiation current density is changed based on the obtained estimated state in order to control the charged state. When the charge estimation parameter is within a threshold designated by a user, current density conditions here are associated with a pattern (material, shape), and the associated data is stored. Once the conditions are determined, when the same pattern in the next location is observed, the determined conditions are read such that the current density conditions can be set depending on patterns.

FIG. 2 illustrates a charge distribution (analysis result) on a sample that is formed when a sample surface (no pattern) is scanned while changing the irradiation current amount of the primary electron beam. The charge distribution is each of results of two-dimensionally scanning a region of 10 μm×10 μm of an SiO2 flat surface at an acceleration voltage of 1 keV and a current of 10 pA to 1 nA. It can be seen that, although the sample is positively charged under conditions where the irradiation current amount is low, the charge is reversed to negative as the irradiation current amount increases.

FIG. 3 illustrates a relationship between an irradiation current amount and an average potential in a field of view. It can be seen that, as the irradiation current amount of the primary electron beam increases, the average potential in the field of view is reversed from positive to negative, and when the average potential (charge amount) in the field of view is zero, the irradiation current amount is present. The reason why the average potential in the field of view is reversed as the irradiation current amount increases is presumed to be that the proportion in which the secondary electrons emitted from the sample are attached to the sample again changes depending on the strength and weakness of charge that is locally formed by electron beam irradiation. As the irradiation current amount increases, the positive charge increases locally, and an excess amount of secondary electrons emitted from the sample surface return to the sample. As a result, a balance between the incident primary electrons and the emitted secondary electrons (excluding the secondary electrons that return to the sample) is lost, and the negative charge progresses.

FIG. 4 illustrates a relationship between a current density and an average potential in a field of view. The phenomenon where the charged state of the sample is reversed to positive or negative occurs due to the influence of charge that is locally formed. Accordingly, the horizontal axis in FIG. 3 can also represent the current irradiation amount of the primary electron beam per time and area, that is, the irradiation current density. Accordingly, FIG. 3 can also be illustrated as a relationship illustrated in FIG. 4. As a device parameter for determining the current density, a scan speed of an electron beam or an observation magnification can be considered in addition to the irradiation current amount. The scan speed is a parameter that affects the above-described time, and the observation magnification is a parameter that affects the area. As a result, by changing any one of the irradiation current, the scan speed, or the observation magnification (observation region), conditions where the average potential in the field of view is zero can be set.

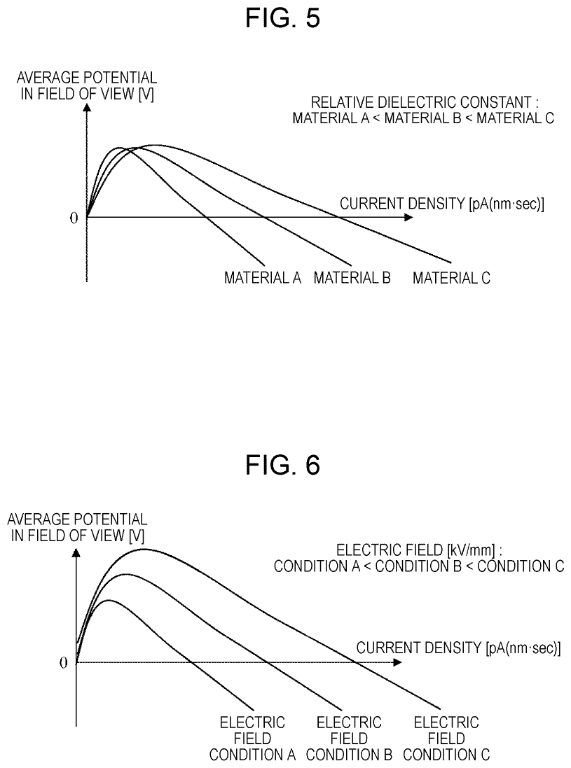

FIG. 5 illustrates a relationship between a current density and an average potential in a field of view depending on material properties of a sample. Here, a relative dielectric constant is used as the material property of the sample. However, as long as the same relationship can be obtained, other material properties may also be used. The phenomenon in which the charged state of the sample is reversed to positive or negative changes depending on the material to be observed as well. As the relative dielectric constant decreases, the charge potential of the surface increases when the same charge is applied. Accordingly, as the relative dielectric constant of the observation target decreases, more secondary electrons return to the sample when the same current density is applied, and the current density at which the average charge in the field of view is reversed from positive to negative decreases. As such, the current density conditions where the influence of charge is minimum change depending on the material of the sample. Therefore, the current density conditions need to change depending on the observation pattern (the material or structure of the sample).

FIG. 6 illustrates a relationship between a current density and an average potential depending on conditions of an electric field (electric field for pulling up secondary electrons emitted from a sample) set on the sample. The phenomenon in which the charged state of the sample is reversed to positive or negative can also be controlled by changing the amount of secondary electrons returning to the sample surface. Under intense electric field conditions for further pulling up secondary electrons, lesser secondary electrons return to the sample. Therefore, the conditions (zero crossing point) where the average potential in the field of view crosses 0 are shifted to the high current density side. Conversely, under conditions where more electrons return to the sample (the electric field is weakened), the zero crossing point is shifted to the low current density side.

By storing the relationship illustrated in FIGS. 3 to 6 in the storage unit 120 in advance in the form of a data table or the like, the arithmetic unit 110 can also control the charged state of the sample using the relationship. For example, the irradiation conditions (zero crossing point) where the charged state of the sample is zero can be read from the data table, and the charged state of the sample can be controlled to zero according to the irradiation conditions. Irradiation conditions for obtaining any positive or negative charged state can also be acquired from the data table.

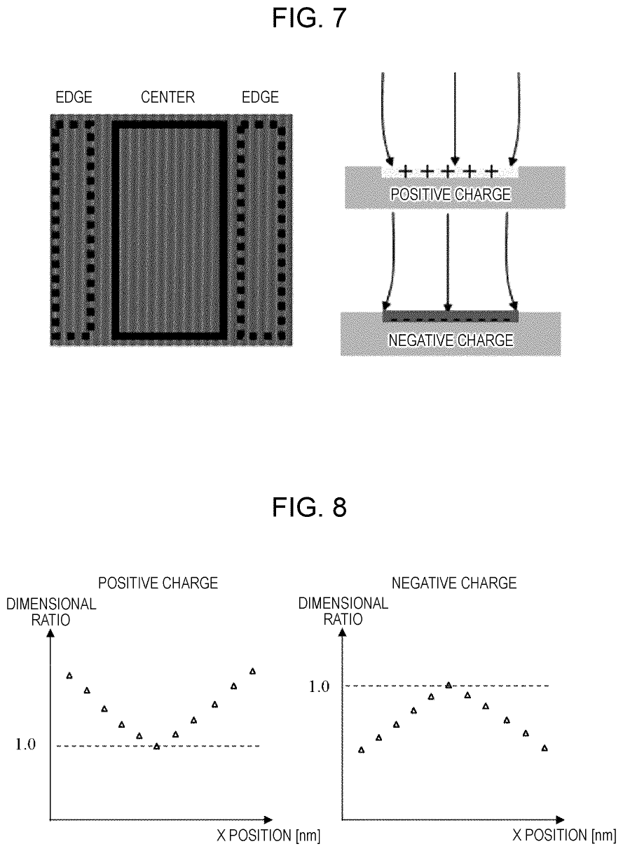

FIG. 7 is a diagram illustrating a charged state of a sample and a deflection action. As illustrated in FIG. 7, primary electrons are affected by a deflection action depending on charge formed in the field of view. In the positive charge, the primary electrons are deflected to the inner side of the field of view. In the negative charge, the primary electrons are deflected to the outer side of the field of view. Here, the amount of electrons deflected by the charge in the field of view varies between the center and edges of the field of view, and as the distance to an edge of the field of view decreases, the influence of deflection increases. That is, a non-uniform magnification change occurs in the field of view depending on the deflection of primary electrons. When the field of view is positively charged, the magnification increases particularly at the edge of the field of view where the amount of deflection is large. The magnification change appears as a parameter that varies depending on patterns. In a case where a Line and Space (L&S) pattern is observed, when the pattern dimension at the center of the field of view and the pattern dimension at the edge of the field of view are compared to each other, the pattern dimension is larger at the edge of the field of view where the magnification is higher. In the negative charge, the magnification at the edge of the field of view decreases, and thus the pattern dimension is less than that at the center of the field of view.

FIG. 8 illustrates an example of results of evaluating a pattern dimensional ratio depending on positions of a sample in each of charged states. Depending on whether the sample is charged positively or negatively, the change tendency of the pattern dimension with respect to the center of the field of view is reversed. As such, the charged state can be estimated based on a distribution of the pattern dimensions in the field of view. By searching for a boundary between irradiation conditions where a change in pattern dimension protrudes downward as illustrated on the left side of FIG. 8 and irradiation conditions where a change in pattern dimension protrudes upward as illustrated on the right side of FIG. 8, the irradiation conditions where the charged state is zero can be specified. Here, the dimensional ratio with respect to the pattern at the center of the field of view is illustrated. However, even when the evaluation is performed using a difference in dimension or an absolute value of dimension, the same tendency appears. In the following description, the same can be applied.

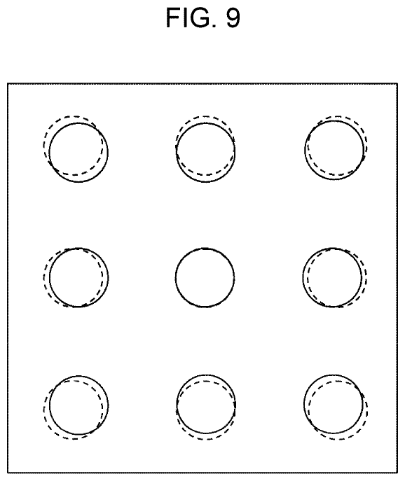

FIG. 9 illustrates one example of a magnification change when a Hole pattern is observed. It can be seen that an edge portion (contour) of a hole read from a solid line image is shifted from a set value indicated by a broken line. Here, the charged state can be estimated based on the amount of shift of center of gravity of the hole.

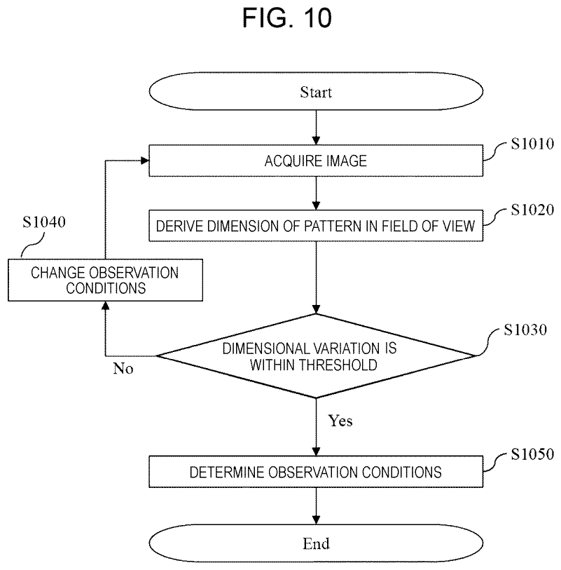

FIG. 10 is a flowchart illustrating a procedure of determining irradiation conditions (observation conditions) of a primary electron beam using the arithmetic unit 110. Here, it is assumed that the L&S pattern distributed in an X direction is formed on the sample. Hereinafter, each of steps in FIG. 10 will be described.

(FIG. 10: Steps S1010 to S1020)

The arithmetic unit 110 acquires an observation image (SEM image) of an observation target pattern under any observation conditions (S1010). The arithmetic unit 110 derives a pattern dimension of the acquired image (S1020). The arithmetic unit 110 stores the observation conditions in S1010 and the pattern dimension acquired in S1020 while associating each other. The pattern dimension can also be handled as one feature amount of the observation image.

(FIG. 10: Step S1030)

The arithmetic unit 110 compares the pattern dimension at the center of the field of view and the pattern dimension at the edge of the field of view to each other. When a variation between the dimension at the center and the dimension at the edge portion is within a threshold, the process proceeds to S1050. When the dimensional variation is within the threshold, the process proceeds to S1040. When the dimensional variation between the center of the field of view and the edge portion of the field of view is zero, the charged state is estimated to be zero. Here, the influence of the charge of the sample on the observation image is minimum.

(FIG. 10: Step S1030: Supplement)

In the flowchart, the line and space pattern in the vertical direction is assumed. Therefore, in the present step, the change in dimension in the X direction is evaluated. The direction for the evaluation can be freely designated depending on the shape of the pattern in the field of view.

(FIG. 10: Step S1040)

The arithmetic unit 110 changes at least one or more among the irradiation current of the primary electron beam, the scan speed, the observation magnification, or the electric field on the sample as observation conditions. After changing the observation conditions, the process returns to S1010, and the same process is repeated.

(FIG. 10: Step S1040: Supplement)

Examples of a specific method of changing the observation conditions include: (a) a method of changing the parameter little by little to detect a current density where the pattern dimension at the center of the field of view matches with that at the edge portion of the field of view; and (b) a method of largely changing the parameter at an initial stage to predict an outline of a change in average potential as illustrated in FIG. 3 or 4 and investigating a current value around which the charged state is reversed to positive or negative in detail to specify the zero crossing point.

(FIG. 10: Step S1050)

The arithmetic unit 110 adopts the current observation conditions.

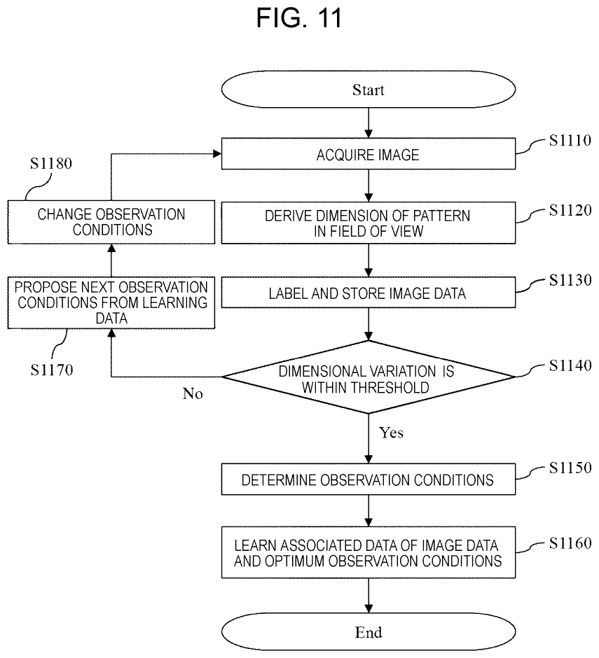

FIG. 11 is a flowchart illustrating a procedure of determining irradiation conditions (observation conditions) of a primary electron beam using AI. It is assumed that a learner learns, by machine learning, a relationship between irradiation conditions and a feature amount of an observation image. Hereinafter, each of steps in FIG. 11 will be described.

(FIG. 11: Steps S1110 to S1130)

The arithmetic unit 110 acquires an observation image of an observation target pattern under any observation conditions (S1110). The arithmetic unit 110 derives a pattern dimension of the acquired image (S1120). The arithmetic unit 110 stores labels image data with the observation conditions and the dimensional variation and stores the labeled data as a data set (S1130).

(FIG. 11: Step S1140)

The arithmetic unit 110 compares the pattern dimension at the center of the field of view and the pattern dimension at the edge of the field of view to each other. When a variation between the dimension at the center and the dimension at the edge portion is within a threshold, the process proceeds to S1150. When the dimensional variation is within the threshold, the process proceeds to S1170.

(FIG. 11: Steps S1150 to S1160)

The arithmetic unit 110 adopts the current observation conditions (S1150). The arithmetic unit 110 associates the observation conditions and the image data with each other and causes the learner to additionally learn the associated data (S1160).

(FIG. 11: Steps S1170 to S1180)

The arithmetic unit 110 acquires observation conditions suitable for the observation image as an output of the learner by inputting the observation image to the learner (S1170). It means that the learner suggests appropriate observation conditions. The arithmetic unit 110 executes adjustment of the optical system or the like according to the observation conditions acquired from the learner (S1180), and returns to S1110.

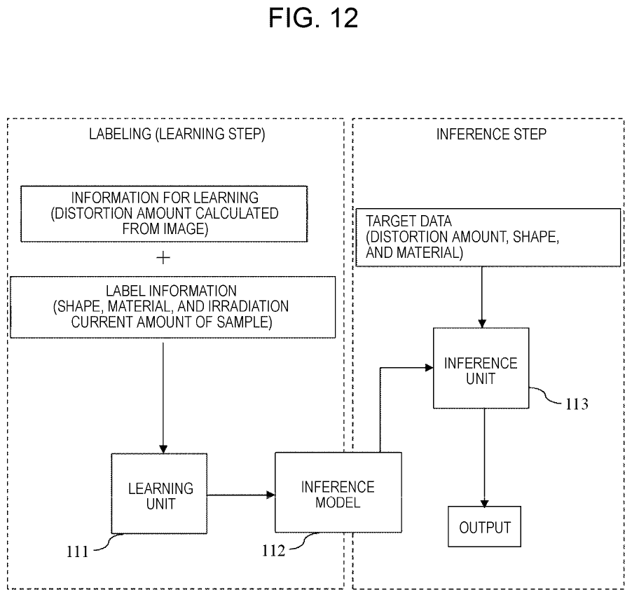

FIG. 12 is a diagram illustrating a configuration of the learner. The learner can be configured as a functional unit in the arithmetic unit 110. The learner is configured by a learning unit 111, an inference model 112, and an inference unit 113.

In the learning step, the learning unit 111 learns a pair of information for learning and label information as learning data to learn a correspondence therebetween. The information for learning is a feature amount of the observation image (for example, the dimensional variation or the like in the L&S pattern or the shift of center of gravity or the like in the Hole pattern). The label information is a parameter (the shape of the sample, the material, the irradiation current amount, or the like) representing the observation conditions. The learning unit 111 outputs the result of executing machine learning as the inference model 112.

One example of a learning method and the inference model 112 will be described. When the L&S pattern is observed under any observation conditions, a difference of the pattern dimension at the edge portion of the field of view from the pattern dimension at the center of the field of view is acquired, and the acquired difference in dimension (information for learning) is paired with the shape, material, and irradiation current amount of the sample (label information) to generate teaching data. Based on the teaching data, the inference model 112 of a relationship between the irradiation current amount and the difference in dimension in a specific wafer (specific material and shape) is constructed. Through the same procedure, each of the inference models 112 of a plurality of wafers (a plurality of materials and shapes) is constructed.

In the inference step, the inference unit 113 acquires the observation conditions (in the present example, the irradiation current amount of the primary electron beam) corresponding to the observation image by inputting the target data (the distortion amount of the observation image, the material of the sample, and the shape of the sample) to the inference model 112. Under the observation conditions, the distortion amount of the observation image can be made to be within a threshold. An observation image is actually acquired using the acquired irradiation current amount, and unless the distortion amount of the observation image is within a threshold, it is assumed that learning does not progress sufficiently. Here, additional learning is executed by using the data set as teaching data. Learning is repeated until the distortion amount is within the threshold. When the material and the shape of the sample cannot be grasped, observation conditions having a certain correlation with the distortion amount can also be acquired by inputting only the distortion amount to the inference model 112.

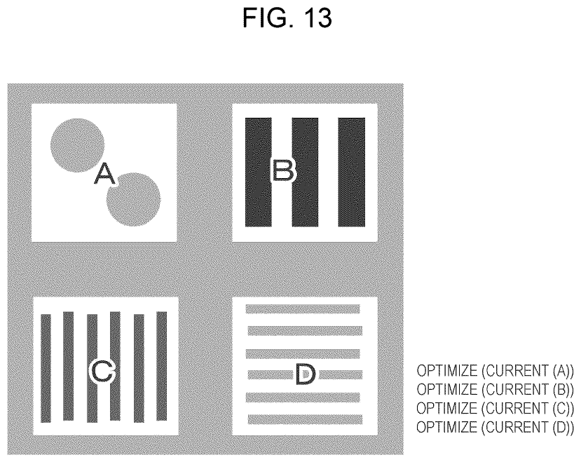

FIG. 13 is a diagram illustrating operating conditions of the present invention. As illustrated in FIG. 13, a plurality of patterns are mixed on a wafer as a measurement target. During the observation, the flowchart of FIG. 11 or 12 can also be executed. By executing the condition search in a location as an observation target, the influence of contamination caused by attachment of gas or the like to the pattern appears. Therefore, it is desirable to acquire observation conditions using the same pattern separately from the observation. Accordingly, the arithmetic unit 110 executes the flowchart of FIG. 11 or 12 in advance depending on patterns having different materials or shapes to obtain optimum observation conditions in advance, and stores data that describes the result in the storage unit 120. During the observation, the obtained optimum conditions reset depending on the observation target. Here, by associating position information and pattern information (which pattern is present at which coordinates) of the wafer with the observation conditions, optical conditions can switch depending on the wafer coordinates to be observed. To minimize a change in optical conditions, an image acquisition order of, for example, collectively measuring the same patterns can also be reflected on a recipe.

When the irradiation current amount of the primary electron beam is changed, the optical axis state needs to be changed. Therefore, after reading preset optical axis conditions, final optical axis adjustment before imaging is executed on another test pattern different from the observation pattern. When the irradiation current conditions are largely changed, in order to reduce blurring of the beam, the aperture angle of the primary electron beam can also be adjusted by the condenser lens (aperture angle adjusting lens) 8.

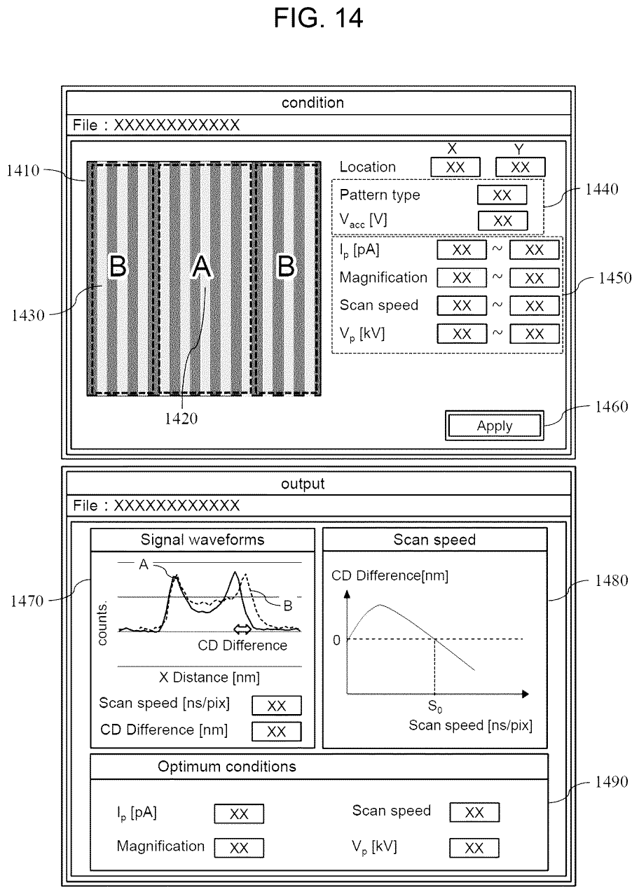

FIG. 14 illustrates one example of a user interface screen for setting operation conditions of the scanning electron microscope 100 by a user. The interface is presented to the user by the arithmetic unit 110 via a display device such as a display.

Designation of an image display unit 1410 is executed on an image (or layout data) that is acquired in advance. For pattern information in the field of view, signal waveform acquisition positions (1420, 1430) can be freely designated by an operator. Any two-dimensional region on the image can be set by being designated using a mouse or the like.

Parameters such as a pattern type to be observed or an acceleration voltage Vacc are set by an input parameter setting unit 1440, one or more condition search ranges among the irradiation current amount Ip, the magnification, the scan speed, and Vp as conditions to be searched for are set by a search parameter setting unit 1450, and an apply button 1460 is pressed. FIG. 14 illustrates one example of an output example when scan speed is used as the sweep parameter. The arithmetic unit 110 sweeps the parameter designated by the user in a designated range, and causes a waveform display unit 1470 to display a difference in pattern dimension of a region B from a region A in the image. A graph of the difference in dimension with respect to the swept parameter is output to a sweep result display unit 1480. Where the absolute value of the difference in dimension is the minimum (So) is set as an optimum condition, and the optimum condition is output to an optimum parameter display unit 1490. The optimum parameter is associated with design data, and the associated data is stored. When the sample having the same material and the same shape is observed next time, the condition can be read and used.

### Second Embodiment

In the first embodiment, the configuration example of estimating the suitable observation conditions using the feature amount of the observation image is described. In a second embodiment of the present invention, a configuration example of estimating a material property of the sample based on an image feature amount (for example, pattern dimension) will be described.

As described above with reference to FIG. 5, the observation parameter where charge is minimized changes depending on the material to be observed. When the material property (here, the relative dielectric constant) illustrated in FIG. 5 is changed, as long as a change in average potential in the field of view with respect to the current density is known in advance, the material property can be estimated based on the dimensional variation by observing the image.

For example, the observation conditions where a difference between the pattern dimension at the center of the field of view and the pattern dimension at the edge portion of the field of view is zero correspond to the zero crossing point in FIG. 5. Therefore, the material corresponding to the current density here can be acquired from the data table in FIG. 5. Instead of the observation conditions where the difference in dimension is zero (charge is zero), (a) observation conditions where the difference in dimension is the maximum, (b) a change amount (gradient) in difference in dimension with respect to a change in observation conditions, or the like is considered to be used to estimate the material. When a change in dimension with respect to a change in observation conditions can be grasped, once only one piece of data is acquired with respect to basic data illustrated in FIG. 5, which curve in FIG. 5 matches with the one piece of data can be seen. Therefore, the material property can be estimated based on one piece of image data.

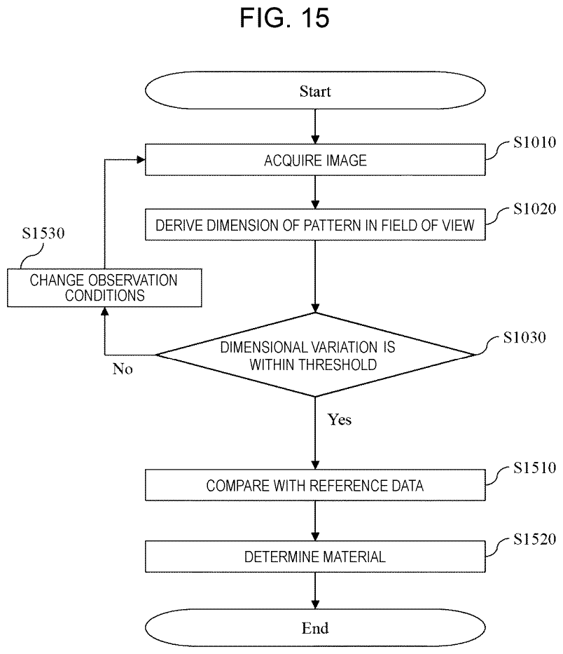

FIG. 15 is a flowchart illustrating a procedure of estimating the material property using the arithmetic unit 110. Here, an example of estimating the material using the observation conditions where the difference in pattern dimension is zero (or is within a threshold range around zero) will be described. The same steps as those of FIG. 10 are represented by the same step numbers, and the description thereof will be omitted. Here, the L&S pattern is assumed to be distributed in the X direction as same as in FIG. 10.

To estimate the material property of the sample based on the feature amount of the observation image, reference data needs to be acquired in advance. The reference data is a data set where a relationship between the observation conditions (the irradiation current amount, the scan speed, and the observation magnification), the pattern dimension, and the material property is recorded. The reference data can be acquired from, for example, learning data for allowing the learner to execute learning in S1130. The learning data is used as correct answer data in the learner, and thus appropriately represents the relationship. Even in the present flowchart, it is assumed that the arithmetic unit 110 acquires the reference data in advance.

(FIG. 15: Steps S1510 to S1520)

By comparing the pattern dimension acquired from the observation image to the reference data, the arithmetic unit 110 specifies which data series in the reference data matches with the observation image (S1510). The arithmetic unit 110 determines the material of the sample based on the data series that matches with the observation image in the reference data

(S1520). For example, the observation conditions where a difference between the pattern dimension at the center of the field of view and the pattern dimension at the edge portion of the field of view is zero are specified in S1030. Therefore, it is only necessary to search for the zero crossing point in the reference data that matches with the observation conditions at the time.

(FIG. 15: Step S1530)

The arithmetic unit 110 acquires conditions different from the current observation conditions among the observation conditions described in the reference data. The process returns to S1010, and the observation image is acquired again using the observation conditions. A method of changing the observation conditions is the same as that of S1040.

In the embodiment, an operation example of estimating the sample property using the learner will be further described as a supplement. The learning step is the same as that of the first embodiment. In the inference step, the inference unit 113 acquires the material of the sample by inputting the distortion amount of the observation image, the shape of the sample, and the irradiation current amount to the inference model 112.

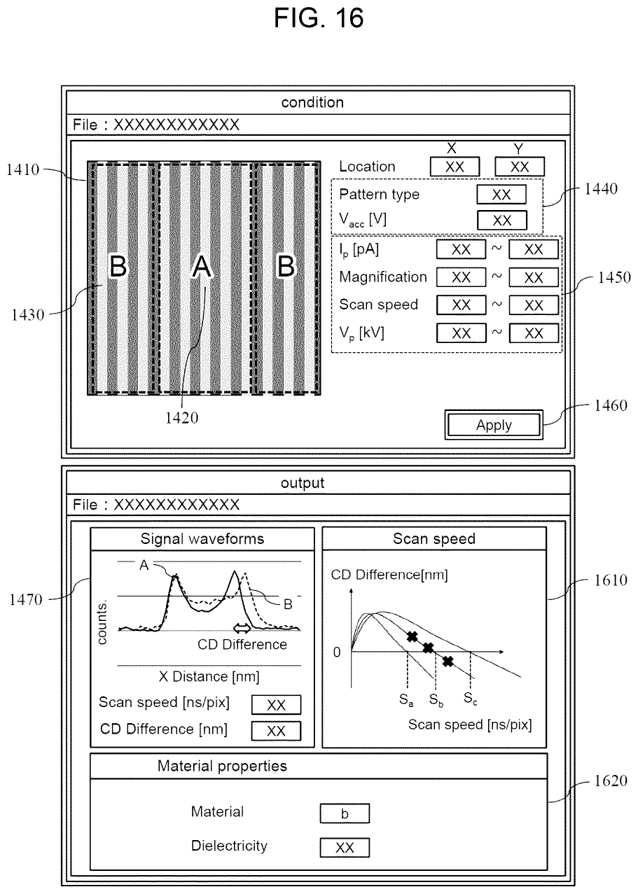

FIG. 16 illustrates one example of a user interface screen according to the embodiment. The same portions as those of the first embodiment are represented by the same reference numerals, and the description thereof will not be repeated. A sweep result display unit 1610 displays the reference data (data representing a relationship between the observation conditions and the difference in pattern dimension). In the search parameter range designated by the user, the difference in pattern dimension between the center of the field of view and the edge portion of the field of view is acquired and displayed as the mark x of the sweep result display unit 1610. Among material properties described in the reference data, one material property that matches with the mark X to the highest degree is represented as the property of the sample. In FIG. 16, the second material property matches with the mark X. A sample property display unit 1620 displays the material properties.

When a curve that matches with the difference in dimension acquired from the observation image is specified in the reference data, the zero crossing point in the reference data does not need to be used. For example, in the example illustrated in FIG. 16, as long as one material property that matches with at least one mark X can be specified, the zero crossing point does not need to be used. The specified material property is associated with the image data and stored.

### Third Embodiment

In the second embodiment, the configuration example of estimating the material of the sample based on the feature amount of the observation image is described. In a third embodiment of the present invention, a configuration example of estimating a structure of the sample from the feature amount of the observation image instead of estimating the material of the sample will be described. Examples of the structure to be estimated include a film thickness of a layer forming the sample.

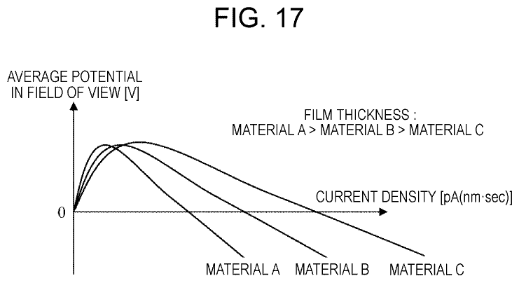

FIG. 17 illustrates reference data of each of three materials A to C having different film thicknesses. The layer material is, for example, SiO2. An observation parameter where charge is minimum changes depending on the structure (film thickness) of the material to be observed as well. As the thickness of SiO2 decreases, the sample is not likely to be positively charged, and thus electrons returning to the sample are not likely to be generated. Therefore, it is presumed that a current value where charge is reversed is also shifted to the high current side. When the material structure (here, the film thickness) is changed, as long as a change in average potential in the field of view with respect to the current density is known in advance, the film thickness can be estimated from a difference between the pattern dimension at the center of the field of view and the pattern dimension at the edge portion of the field of view in the observation image.

Examples of a method of estimating the film thickness are the same as those of the second embodiment including: (a) a method of estimating the film thickness using the observation conditions where the difference in dimension is zero; (b) a method of estimating the film thickness using the observation conditions where the difference in dimension is maximum; (c) a method of estimating the film thickness using the change amount (gradient) in difference in dimension with respect to a change in observation conditions; and (d) a method of estimating the film thickness from one piece of image data when the change in dimension with respect to the change in observation conditions can be grasped.

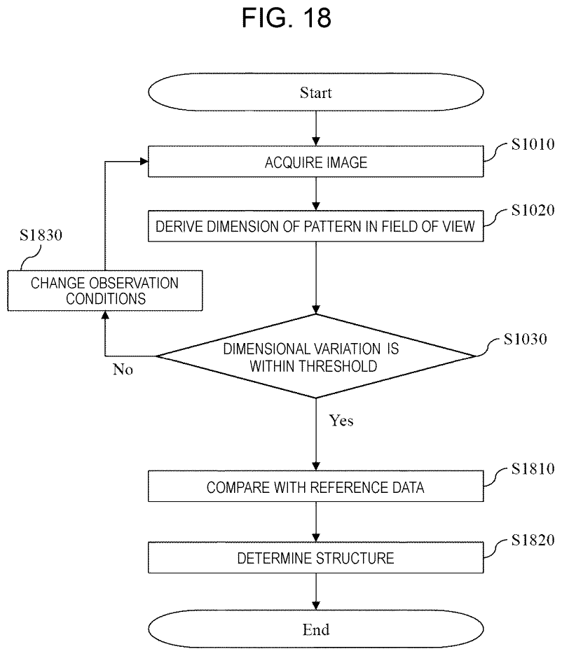

FIG. 18 is a flowchart illustrating a procedure of estimating the film thickness using the arithmetic unit 110. Here, an example of estimating the film thickness using the observation conditions where the difference in pattern dimension is zero (or is within a threshold range around zero) will be described. The same steps as those of FIG. 10 are represented by the same step numbers, and the description thereof will be omitted. Here, the L&S pattern is assumed to be distributed in the X direction as same as in FIG. 10. It is assumed that the reference data is acquired in advance.

S1810 to S1830 are the same as S1510 to S1530, respectively. Note that, since the reference data in the embodiment describes the relationship between the observation conditions and the film thickness, the film thickness of the sample is acquired in S1820.

In the embodiment, an operation example of estimating the film thickness using the learner will be further described as a supplement. The learning step is the same as that of the first embodiment. In the inference step, the inference unit 113 acquires the film thickness of the sample by inputting the distortion amount of the observation image, the material of the sample, and the irradiation current amount to the inference model 112.

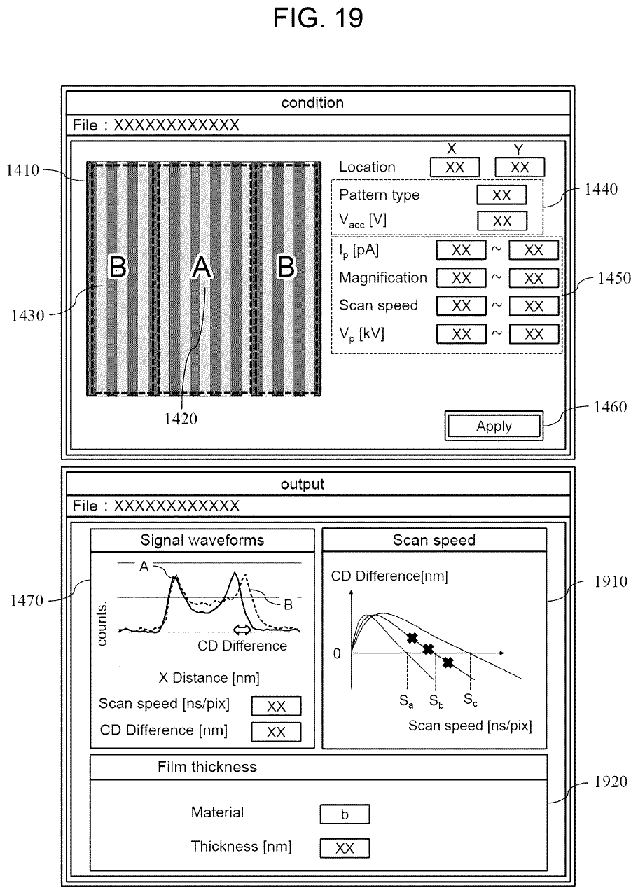

FIG. 19 illustrates one example of a user interface screen according to the embodiment. The same portions as those of the first embodiment are represented by the same reference numerals, and the description thereof will be omitted. A sweep result display unit 1910 displays the reference data (data representing a relationship between the observation conditions and the difference in pattern dimension). In the search parameter range designated by the user, the difference in pattern dimension between the center of the field of view and the edge portion of the field of view is acquired and displayed as the mark X of the sweep result display unit 1910. Among film thicknesses described in the reference data, one film thickness that matches with the mark X to the highest degree is represented as the film thickness of the sample. In FIG. 19, the second film thickness matches with the mark X. A sample film thickness display unit 1920 displays the film thickness. As same as the second embodiment, the zero crossing point of the reference data is not necessarily used. <Regarding Modification Example of Present Invention>

The present invention is not limited to the embodiments described-above and includes various modification examples. For example, the embodiments have been described in detail to easily describe the present invention, and the present invention does not necessarily include all the configurations described above. A part of the configuration of one embodiment can be replaced with the configuration of another embodiment. The configuration of one embodiment can be added to the configuration of another embodiment. Addition, deletion, and replacement of another configuration can be made for a part of the configuration each of the embodiments.

In the above-described embodiments, the distortion amount of the observation image can also be estimated based on the material of the sample, the shape of the sample, and the observation conditions (the irradiation current amount of the primary electron beam). For example, in the learning step of the learner, the same learning as that of the above-described embodiments is executed. In the inference step, the inference unit 113 can acquire the distortion amount of the observation image by inputting the material of the sample, the shape of the sample, and the observation conditions to the inference model 112. The charged state of the sample surface can be estimated based on the potential measurement result of the sample surface by the energy filter 12. Therefore, the charged state can also be learned. Here, the distortion amount or the sample surface potential estimated from the distortion amount can be obtained from the inference model 112.

In the above-described embodiments, the arithmetic unit 110 and each of the functional units in the arithmetic unit 110 can also be configured by hardware such as a circuit device that implements the function or can also be configured by an arithmetic device executing software that implements the function.

In the above-described embodiments, the SEM is described as the example of the charged particle beam device. However, the present invention is applicable to other charged particle beam devices that acquire an observation image of a sample using a charged particle beam.

### REFERENCE SIGN LIST

1: electron gun
2: electron beam
3: condenser lens
4: primary electron deflector
5: objective lens
6: sample
7: signal electron deflector
8: condenser lens (aperture angle adjusting lens)
9: detector
10: signal electron diaphragm
11: signal electron deflector
12: energy filter
13: detector
100: scanning electron microscope

1. A charged particle beam device that irradiates a sample with a charged particle beam, the charged particle beam device comprising:
a detector configured to irradiate the sample with the charged particle beam to detect secondary charged particles generated from the sample and to output a detection signal representing a signal intensity of the secondary charged particles; and
an arithmetic unit configured to generate an observation image of the sample using the detection signal, wherein
the arithmetic unit specifies irradiation conditions of the charged particle beam where a charged state of the sample switches between positive charge and negative charge, and
the arithmetic unit adjusts the irradiation conditions according to a first relationship between the specified irradiation conditions and the irradiation conditions where the observation image is acquired.

2. The charged particle beam device according to claim 1, wherein
the arithmetic unit acquires a feature amount of the observation image, and
the arithmetic unit specifies the irradiation conditions where the feature amount is in a desired range according to the first relationship such that the irradiation conditions are adjusted to obtain the feature amount in the desired range.

3. The charged particle beam device according to claim 2, wherein
the arithmetic unit calculates, as the feature amount, a size of a pattern that is formed on the sample, and
the arithmetic unit adjusts the irradiation conditions according to the first relationship such that a variation distribution in the size of the pattern in an observation field of view of the sample is within a threshold range.

4. The charged particle beam device according to claim 3, wherein
the arithmetic unit estimates the charged state of the sample based on which one of a first size of the pattern at a center portion of the observation field of view and a second size of the pattern at a position of the observation field of view other than the center portion is larger,
when the first size is smaller, the arithmetic unit estimates that the sample is positively charged, and
when the second size is smaller, the arithmetic unit estimates that the sample is negatively charged.

5. The charged particle beam device according to claim 4, wherein
the arithmetic unit specifies the irradiation conditions where the charged state of the sample switches between positive charge and negative charge by searching for a boundary between the irradiation conditions where the first size is smaller and the irradiation conditions where the second size is smaller.

6. The charged particle beam device according to claim 4, wherein
when the pattern is a Line and Space pattern, the arithmetic unit uses, as the variation distribution, at least any one of a ratio between the first size and the second size, a difference between the first size and the second size, or a distribution of the size, and
when the pattern is a hole, the arithmetic unit uses, as the variation distribution, at least any one of a shift of center of gravity of an opening of the hole or a shape deviation of an opening of the hole.

7. The charged particle beam device according to claim 1, wherein
the arithmetic unit estimates the charged state of the sample according to a feature amount of the observation image and the first relationship, and
the arithmetic unit adjusts the irradiation conditions according to the estimated charged state such that the charged state of the sample is in a desired range.

8. The charged particle beam device according to claim 7, further comprising a storage unit configured to store charge property data that describes a result of measuring in advance a second relationship between the charged state and the irradiation conditions, wherein
the arithmetic unit controls the irradiation conditions according to the second relationship described in the charge property data such that the charged state is in the desired range.

9. The charged particle beam device according to claim 8, wherein
the arithmetic unit adjusts the irradiation conditions by adjusting at least any one of a current amount of the charged particle beam,
an area density of a current amount of the charged particle beam,
a time density of a current amount of the charged particle beam,
a scan speed of the charged particle beam, or
an observation magnification of an area on the sample observed using the charged particle beam.

10. The charged particle beam device according to claim 8, wherein
the charge property data describes the second relationship depending on a material of the sample, and
the arithmetic unit controls the irradiation conditions according to the second relationship corresponding to the material of the sample such that the charged state is in the desired range.

11. The charged particle beam device according to claim 8, further comprising an electrode configured to generate an electric field that acts on the secondary charged particles, wherein
the charge property data describes the second relationship depending on an intensity of the electric field, and
the arithmetic unit controls at least any one of the irradiation conditions or the intensity of the electric field according to the second relationship corresponding to the intensity of the sample such that the charged state is in the desired range.

12. The charged particle beam device according to claim 2, further comprising a user interface configured to designate a range of the irradiation conditions, wherein
the arithmetic unit searches for the irradiation conditions where the feature amount is in the desired range in the range of the irradiation conditions designated via the user interface, and presents the search result to the user interface.

13. The charged particle beam device according to claim 2, further comprising a storage unit configured to store condition data that describes a result of measuring in advance the irradiation conditions of the charged particle beam where the feature amount is in the desired range depending on a second pattern that is the same as a first pattern in the sample, wherein
the arithmetic unit adjusts the irradiation conditions for the first pattern according to the irradiation conditions described in the condition data.

14. The charged particle beam device according to claim 2, further comprising a learner configured to learn, by machine learning, a relationship between a shape parameter representing a shape of a pattern in the sample, a material of the sample, the irradiation conditions, and the feature amount, wherein
the arithmetic unit specifies the irradiation conditions where the feature amount is in the desired range by searching for the irradiation conditions where the desired range is obtained using the irradiation conditions output from the learner.

15. The charged particle beam device according to claim 1, wherein
when an irradiation amount of the charged particle beam is changed, the arithmetic unit readjusts a parameter regarding an optical axis of the charged particle beam according to the changed irradiation amount.

16. The charged particle beam device according to claim 1, further comprising an optical element configured to adjust an aperture angle of the charged particle beam, wherein
when an irradiation amount of the charged particle beam is changed, the arithmetic unit causes the optical element to readjust the aperture angle according to the changed irradiation amount such that blurring of the charged particle beam is reduced.

17. The charged particle beam device according to claim 1, further comprising a storage unit configured to store reference data that describes a third relationship between a property of the sample, a feature amount of the observation image, and the irradiation conditions, wherein
the arithmetic unit estimates the property of the sample by referring to the reference data using the first relationship.

18. The charged particle beam device according to claim 17, wherein
the reference data describes a material of the sample as the property of the sample, and
the arithmetic unit estimates the material of the sample by referring to the reference data.

19. The charged particle beam device according to claim 17, wherein
the reference data describes a shape parameter representing a structure of the sample as the property of the sample,
the arithmetic unit estimates the structure of the sample by referring to the reference data.

20. The charged particle beam device according to claim 17, further comprising a learner configured to learn the reference data by machine learning, wherein
the arithmetic unit acquires the property of the sample as an output from the learner by inputting the irradiation conditions and the feature amount to the learner.

21. The charged particle beam device according to claim 2, further comprising a storage unit configured to store data that describes a fourth relationship between a structure of the sample, a material of the sample, the irradiation conditions, and the feature amount, wherein
the arithmetic unit estimates the feature amount by referring to the fourth relationship using the structure of the sample, the material of the sample, and the irradiation conditions.
